(19) United States
(12) Patent Application Publication
(10) Pub. No.: US 2025/0024594 A1
(43) Pub. Date: Jan. 16, 2025

(54) FLEXIBLE SUBSTRATE AND BUS BAR MODULE

(71) Applicant: Yazaki Corporation, Tokyo (JP)

(72) Inventor: Hidehiko SHIMIZU, Shizuoka (JP)

(73) Assignee: Yazaki Corporation, Tokyo (JP)

(21) Appl. No.: 18/768,352

(22) Filed: Jul. 10, 2024

(30) Foreign Application Priority Data
Jul. 12, 2023 (JP) 2023-114566

(51) Int. Cl. H05K 1/02; H01M 50/507; H01M 50/519; H05K 1/18; H05K 3/28

(52) U.S. Cl. CPC H05K 1/0272; H01M 50/507; H01M 50/519; H05K 1/0281; H05K 1/181; H05K 1/189; H05K 3/28

(57) ABSTRACT

A flexible substrate includes an electronic component, a base film, a conductor circuit, and a coverlay. The electronic component has an electrode. The conductor circuit is formed on a second surface (lower side surface in a vertical direction) of the base film, and has a joint region to which the electrode is jointed using a joint material. The coverlay covers at least a part of a second surface (lower side surface in the vertical direction) of the conductor circuit, and has an opening exposing the joint region to the outside.

### CROSS-REFERENCE TO RELATED APPLICATIONS

The present application is based on, and claims priority from Japanese Patent Application No. 2023-114566, filed on Jul. 12, 2023, the entire contents of which are incorporated herein by reference.

### TECHNICAL FIELD

The disclosure relates to a flexible substrate and a bus bar module.

### BACKGROUND

Conventionally, a flexible substrate has been known in which an electronic component is mounted on a flexible printed circuit (hereinafter abbreviated as FPC).

In the FPC, a conductor circuit is formed on a surface of a base film, and at least a part of a surface of the conductor circuit is covered with an insulating coverlay.

In such a configuration, when an electronic component is mounted on the FPC, an electrode or a terminal of the electronic component is joined to a joint region of the conductor circuit that is exposed to the outside in an opening of the coverlay, using a joint material such as solder.

JP 2017-27831 A discloses a configuration in which a resin is applied to the opening of the coverlay and the opening is covered with a resin film, in the flexible substrate on which the electronic component is mounted on the FPC.

With such a configuration, the joint between the electronic component and the conductor circuit is covered with the resin film in the opening of the coverlay, thereby increasing a moisture resistance of the joint. The joint includes the electrode of the electronic component, the joint material, and the joint region of the conductor circuit. Thus, even when dew condensation occurs in the opening of the FPC, it is possible to avoid a short circuit of the electronic component due to dew condensation water.

### SUMMARY OF THE INVENTION

However, in general, when a resin is applied to form a resin film, it is difficult to control a film thickness. For example, when a thin resin film is formed, there is a possibility that dew condensation water enters the joint between the electronic component and the conductor circuit, which may cause a short circuit of the electronic component.

For this reason, when increasing the moisture resistance of the joint by applying resin to form a resin film, the yield at the time of manufacturing may be reduced. Accordingly, further improvements have been required to increase the moisture resistance of the joint between the electronic component and the conductor circuit while suppressing a reduction in yield at the time of manufacturing.

The disclosure has been made in view of such problems of the conventional art. An object of the disclosure is to provide a flexible substrate and a bus bar module that can increase a moisture resistance of a joint between an electronic component and a conductor circuit while suppressing a reduction in yield at the time of manufacturing.

A flexible substrate according to a first aspect of the embodiments includes: an electronic component that has an electrode; a base film; a conductor circuit that is formed on a lower side surface of the base film in a vertical direction, and has a first joint region to which the electrode is jointed using a joint material; and a coverlay that covers at least a part of a lower side surface of the conductor circuit in the vertical direction, and has a first opening exposing the first joint region to an outside.

A bus bar module according to a second aspect of the embodiments includes: a case that is assembled to a cell module having a plurality of single cells; a bus bar that is supported by the case, and electrically connects positive and negative electrode terminals of adjacent single cells among the plurality of single cells; and a flexible substrate that is housed in the case. The flexible substrate has: a trunk portion; and a branch portion that branches from the trunk portion, is folded back so as to intersect with the trunk portion in a plan view, and is electrically connected to the bus bar. An end portion of the branch portion has: an electronic component that has an electrode; a base film; a conductor circuit that is formed on a lower side surface of the base film in a vertical direction, and has a first joint region and a second joint region; a coverlay that covers at least a part of a lower side surface of the conductor circuit in the vertical direction, and has a first opening exposing the first joint region to an outside and a second opening exposing the second joint region to the outside; and a metal plate. The coverlay further covers a part of a lower side surface of the base film in the vertical direction, except for a region exposed to the outside in the first opening. The metal plate is provided on a lower side surface of the coverlay in the vertical direction, and surrounds the electronic component. In the first opening, the electrode is joined to the first joint region using a joint material. In the second opening, one end of the metal plate is joined to the second joint region. Another end of the metal plate is joined to the bus bar. The electronic component is electrically connected to the bus bar via the conductor circuit and the metal plate.

According to the embodiments, it is possible to provide a flexible substrate and a bus bar module that can increase a moisture resistance of a joint between an electronic component and a conductor circuit while suppressing a reduction in yield at the time of manufacturing.

### BRIEF DESCRIPTION OF DRAWINGS

FIG. 1 is a bottom view of a flexible substrate according to a first embodiment.

FIG. 2 is an end view along line II-II of FIG. 1.

FIG. 3 is an end view of a flexible substrate according to a first modified example of the first embodiment.

FIG. 4 is a diagram for explaining a state of a flexible substrate according to a second modified example of the first embodiment before an electronic component is mounted on a flexible printed circuit.

FIG. 5 is a diagram for explaining a state of the flexible substrate according to the second modified example of the first embodiment after the electronic component is mounted on the flexible printed circuit.

FIG. 6 is a cross-sectional view of a flexible substrate according to a second embodiment.

FIG. 7 is a cross-sectional view of a flexible substrate according to a modified example of the second embodiment.

FIG. 8 is a plan view of a bus bar module including a flexible substrate according to a third embodiment.

FIG. 9 is a cross-sectional view along line IX-IX of FIG. 8.

FIG. 10 is a diagram for explaining a state of the flexible substrate according to the third embodiment before folding back a plurality of branch portions branched from a trunk portion of a flexible printed circuit.

FIG. 11 is a diagram for explaining a state of the flexible substrate according to the third embodiment after folding back the plurality of branch portions branched from the trunk portion of the flexible printed circuit.

FIG. 12 is a diagram for explaining a state of the flexible substrate according to the third embodiment before mounting an electronic component on an end portion of a branch portion of the flexible printed circuit.

FIG. 13 is a diagram for explaining a state of the flexible substrate according to the third embodiment after mounting the electronic component on the end portion of the branch portion of the flexible printed circuit.

FIG. 14 is a plan view of a flexible substrate according to a modified example of the third embodiment.

### DETAILED DESCRIPTION OF THE INVENTION

Hereinafter, a flexible substrate according to first to third embodiments will be described in detail with reference to the drawings. The dimensional ratio of the drawings is exaggerated for the sake of explanation, and may differ from the actual ratio. Further, the same functions and elements are denoted by the same or similar reference numerals, and a description thereof will be omitted as appropriate.

### First Embodiment

(Configuration of flexible substrate)

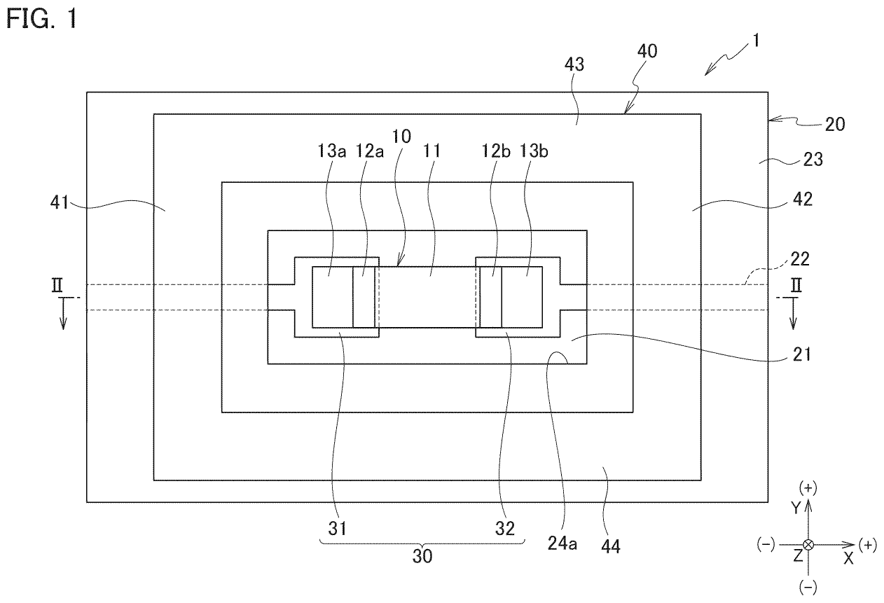

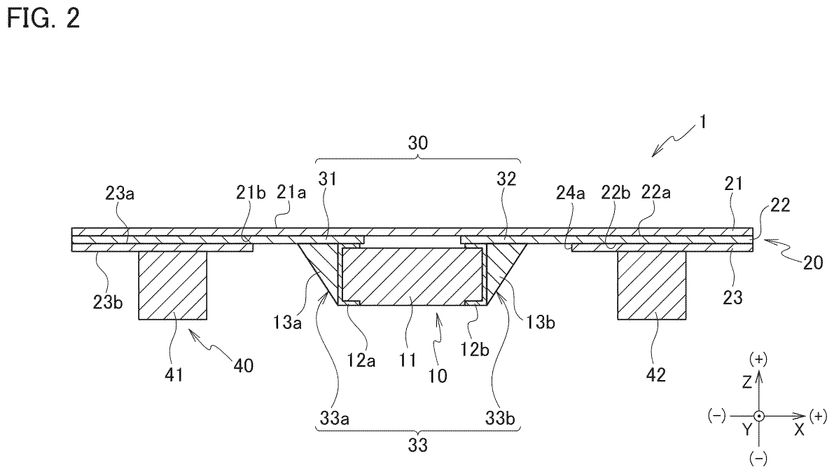

First, a configuration of a flexible substrate 1 according to the present embodiment will be described. FIG. 1 is a bottom view of the flexible substrate 1. FIG. 2 is an end view along line II-II of FIG. 1. In FIGS. 1 and 2, only a part of the flexible substrate 1 is illustrated in order to clearly indicate a mounting portion of an electronic component 10.

An X direction illustrated in FIGS. 1 and 2 corresponds to a longitudinal direction of the flexible substrate 1. A Y direction illustrated in FIGS. 1 and 2 corresponds to a width direction of the flexible substrate 1 and is orthogonal to the X direction. A Z direction illustrated in FIGS. 1 and 2 corresponds to a height direction of the flexible substrate 1 and is orthogonal to the X direction and the Y direction. In the present embodiment, the Z direction corresponds to the vertical direction.

The X direction and the Y direction may correspond to the width direction and the longitudinal direction of the flexible substrate 1, respectively.

A +X side and a −X side illustrated in FIGS. 1 and 2 correspond to a front side and a rear side of the flexible substrate 1, respectively. A +Y side and a −Y side illustrated in FIGS. 1 and 2 correspond to a left side and a right side of the flexible substrate 1 toward the front side of the flexible substrate 1, respectively. A +Z side and a −Z side illustrated in FIGS. 1 and 2 correspond to an upper side and a lower side of the flexible substrate 1, respectively.

As illustrated in FIGS. 1 and 2, the flexible substrate 1 includes an electronic component 10 and a flexible printed circuit (hereinafter abbreviated as FPC) 20. The electronic component 10 has a main body 11 and electrodes 12a and 12b. The electronic component 10 is, for example, a fuse. The electronic component 10 is not limited to a fuse and may be a resistor, capacitor, coil, semiconductor, or the like.

The main body 11 includes an element (not illustrated) therein. The element is electrically connected to the electrode 12a at one end (−X side) of the main body 11 and to the electrode 12b at the other end (+X side) of the main body 11. If the electronic component 10 is a fuse, the main body 11 includes a fuse resistor therein.

The electrodes 12a and 12b are joined to a conductor circuit 22 of the FPC 1 using a joint material such as solder. Fillets 13a, 13b on which the joint material is accumulated are formed respectively at the portions where the electrodes 12a and 12b are joined to the conductor circuit 22 using the joint material. Since the electrodes 12a and 12b are electrically connected to the conductor circuit 22 via the fillets 13a and 13b, the fillets 13a and 13b are also referred to as connection portions.

The FPC 20 has flexibility, and includes a base film 21, the conductor circuit 22 and a coverlay 23. The base film 21 has flexibility and is formed in a plan shape. The base film 21 is a base material of the FPC 20 and defines the overall shape of the FPC 20. The base film 21 is formed of, for example, a polyimide resin having excellent heat resistance.

The base film 21 has a first surface 21a and a second surface 21b extending along the longitudinal direction of the flexible substrate 1. The first surface 21a and the second surface 21b face in opposite directions to each other. In a state in which the flexible substrate 1 is mounted on the product, the first surface 21a and the second surface 21b face upward (+Z side) and downward (−Z side) in the flexible substrate 1, respectively (see FIGS. 1 and 2). For this reason, the first surface 21a and the second surface 21b are also referred to as an upper side surface in the vertical direction and a lower side surface in the vertical direction, respectively.

The conductor circuit 22 is formed on the second surface 21b of the base film 21. Specifically, a pattern layer constituting the conductor circuit 22 is stacked on the base film 21 on the second surface 21b side of the base film 21 (see FIG. 2).

The conductor circuit 22 has a first surface 22a and a second surface 22b extending along the longitudinal direction of the flexible substrate 1. The first surface 22a and the second surface 22b face in opposite directions to each other. In a state in which the flexible substrate 1 is mounted on the product, the first surface 22a and the second surface 22b face upward (+Z side) and downward (−Z side) in the flexible substrate 1, respectively (see FIGS. 1 and 2). For this reason, the first surface 22a and the second surface 22b are also referred to as the upper side surface in the vertical direction and the lower side surface in the vertical direction.

In a state in which the conductor circuit 22 is stacked on the base film 21, the first surface 22a of the conductor circuit 22 abuts on the second surface 21b of the base film 21. The conductor circuit 22 is also called a Cu pattern.

In the present embodiment, the conductor circuit 22 extends along the longitudinal direction of the flexible substrate 1 in the portion where the electronic component 10 is mounted on the FPC 20; however, the present embodiment is not limited thereto. Depending on the use state of the flexible substrate 1, the conductor circuit 22 may extend in a direction other than the longitudinal direction of the flexible substrate 1.

The conductor circuit 22 has pads 31 and 32. The pads 31 and 32 are physically separated from each other, and constitute a joint region 30 of the conductor circuit 22. The electrode 12a of the electronic component 10 is joined to the pad 31. The electrode 12b of the electronic component 10 is joined to the pad 32.

The coverlay 23 is an insulating protective film, and except for one region of the second surface 21b of the base film 21 and one region of the second surface 22b of the conductor circuit 22 (joint region 30), which are exposed to the outside in an opening 24a which will be described later, the coverlay 23 covers the second surface 21b of the base film 21 and the second surface 22b of the conductor circuit 22 (see FIGS. 1 and 2). Thus, the coverlay 23 is stacked on a part of the base film 21 and a part of the conductor circuit 22 on the second surface 21b side of the base film 21 and on the second surface 22b side of the conductor circuit 22.

With this configuration, the coverlay 23 covers at least a part of the second surface 22b of the conductor circuit 22. As a result, a part of the conductor circuit 22 is insulated and protected by the coverlay 23.

The coverlay 23 has a first surface 23a and a second surface 23b extending along the longitudinal direction of the flexible substrate 1. The first surface 23a and the second surface 23b face in opposite directions to each other. In a state in which the flexible substrate 1 is mounted on the product, the first surface 23a and the second surface 23b face upward (+Z side) and downward (−Z side) in the flexible substrate 1, respectively (see FIGS. 1 and 2). For this reason, the first surface 23a and the second surface 23b are also referred to as the upper side surface in the vertical direction and the lower side surface in the vertical direction.

In a state in which the coverlay 23 is stacked on a part of the base film 21 and a part of the conductor circuit 22, the first surface 23a of the coverlay 23 is bonded to a part of the second surface 21b of the base film 21 and a part of the second surface 22b of the conductor circuit 22.

The coverlay 23 has an opening 24a at the portion where the electronic component 10 is mounted on the FPC 20. In the opening 24a, the joint region 30 (pads 31, 32) of the conductor circuit 22 to which the electrodes 12a and 12b of the electronic component 10 are joined is exposed to the outside. In the opening 24a, the pad 31 forms a −X side end portion of the conductor circuit 22, and the pad 32 forms a +X side end portion of the conductor circuit 22. The opening 24a is also called the first opening. The joint region 30 is also called the first joint region.

In the present embodiment, the opening 24a is formed in a rectangular shape, and a long side and a short side of the opening 24a extend along the longitudinal direction and the width direction of the flexible substrate 1, respectively; however, the present embodiment is not limited thereto. Depending on the shape of the joint region 30 of the conductor circuit 22, the opening 24a may be formed in a shape other than a rectangular shape. Further, even when the opening 24a is formed in a rectangular shape, depending on the arrangement of the joint region 30 of the conductor circuit 22, the long side may extend in a direction other than the longitudinal direction of the flexible substrate 1, and the short side may extend in a direction other than the width direction of the flexible substrate 1.

The opening 24a is surrounded by a metal plate 40 provided on the second surface 23b of the coverlay 23. The metal plate 40 has a first portion 41, a second portion 42, a third portion 43, and a fourth portion 44. The first portion 41 is provided to project from the second surface 23b of the coverlay 23 along the width direction of the flexible substrate 1 on the −X side with respect to the opening 24a. The second portion 42 is provided to project from the second surface 23b of the coverlay 23 along the width direction of the flexible substrate 1 on the +X side with respect to the opening 24a.

The third portion 43 is provided to project from the second surface 23b of the coverlay 23 along the longitudinal direction of the flexible substrate 1 on the +Y side with respect to the opening 24a. The fourth portion 44 is provided to project from the second surface 23b of the coverlay 23 along the longitudinal direction of the flexible substrate 1 on the −Y side with respect to the opening 24a. A −X side end portion and a +X side end portion of the third portion 43 are connected to a +Y side end portion of the first portion 41 and a +Y side end portion of the second portion 42, respectively. A −X side end portion and a +X side end portion of the fourth portion 44 are connected to a −Y end portion of the first portion 41 and a −Y side end portion of the second portion 42, respectively.

With this configuration, the metal plate 40 surrounds the electronic component 10. In the present embodiment, since the rigidity of the FPC 20 can be increased by providing the metal plate 40, a reinforcing plate is not provided on the first surface 21a of the base film 21.

### (Mounting of Electronic Component)

Next, a method for mounting the electronic components 10 on the FPC 20 will be described. As an example, a method for mounting the electronic components 10 on the FPC 20 when solder is used as a joint material will be described.

First, in a state of the second surface 23b of the coverlay 23 facing upward (+Z side) in the flexible substrate 1, solder paste is printed on the pads 31 and 32 exposed to the outside in the opening 24a of the coverlay 23. When the printing of the solder paste is completed, the electrodes 12a and 12b of the electronic component 10 are placed on the pads 31 and 32, respectively.

Next, the flexible substrate 1 is put into a reflow furnace. When the flexible substrate 1 is put into the reflow furnace, the pads 31 and 32 are heated and soldered in the reflow furnace. As a result, the electrodes 12a and 12b are joined to the pads 31 and 32, respectively, and the electronic component 10 is mounted on the FPC 20.

In manufacturing the product, the FPC 20 is turned over, and the flexible substrate 1 is mounted on the product in a state of the second surface 23b of the coverlay 23 facing downward (−Z side) of the flexible substrate 1. The region of the FPC 20 including the portion where the electronic component 10 is mounted may be folded, causing the second surface 23b of the coverlay 23 to face downward (−Z side) in the flexible substrate 1.

The electrodes 12a and 12b of the electronic component 10, the joint material, and the joint region 30 of the conductor circuit 22 constitute a joint 33 between the electronic component 10 and the conductor circuit 22. Specifically, the electrode 12a of the electronic component 10, the fillet 13a, and the pad 31 of the conductor circuit 22 constitute a joint 33a between the electronic component 10 and the conductor circuit 22. Similarly, the electrode 12b of the electronic component 10, the fillet 13b, the pad 32 of the conductor circuit 22 constitute a joint 33b between the electronic component 10 and the conductor circuit 22.

### Action and Effect

According to the present embodiment, the flexible substrate 1 includes the electronic component 10, the base film 21, the conductor circuit 22, and the coverlay 23. The electronic component 10 has the electrodes 12a and 12b. The conductor circuit 22 is formed on the second surface (the lower side surface in the vertical direction) 21b of the base film 21, and has the joint region 30 to which the electrodes 12a and 12b are joined using a joint material. The coverlay 23 covers at least a part of the second surface (the lower side surface in the vertical direction) 22b of the conductor circuit 22, and has the opening 24a which exposes the joint region 30 to the outside.

In the present embodiment, with the configuration described above, the electrodes 12a and 12b of the electronic component 10, the joint material, and the joint region 30 of the conductor circuit 22, which are included in the joint 33 between the electronic component 10 and the conductor circuit 22, are arranged on the second surface 21b of the base film 21. Here, the second surface 21b of the base film 21 faces the lower side in the vertical direction.

For this reason, even when dew condensation occurs in the opening 24a of the FPC 20, dew condensation water drains to the lower side in the vertical direction (the ground side). Thus, with a simple configuration, it is possible to prevent the dew condensation water from accumulating in the joint 33, thereby reliably avoiding a short circuit of the electronic component 10. Accordingly, in the flexible substrate 1, it is possible to increase a moisture resistance of the joint 33 between the electronic component 10 and the conductor circuit 22 while suppressing a reduction in yield at the time of manufacturing.

According to the present embodiment, the flexible substrate 1 further includes the metal plate 40. The coverlay 23 further covers a part of the second surface (the lower side surface in the vertical direction) 21b of the base film 21, except for the region exposed to the outside in the opening 24a. The metal plate 40 is provided on the second surface (the lower side surface in the vertical direction) 23b of the coverlay 23, and surrounds the electronic component 10. A reinforcing plate is not provided on the first surface (the upper side surface in the vertical direction) 21a of the base film 21.

Generally, in a case where an electronic component is mounted on an FPC, the FPC has excellent flexibility, and thus when an external force acts on the FPC due to vibration, contact, or the like, which causes the FPC to bend. As a result, a mechanical stress is applied to the electronic component, and the joint between the electronic component and the conductor circuit. For this reason, there is a possibility of wire breakage and connection failure in the flexible substrate.

In order to handle such problems, when the electronic component is mounted on the FPC, a reinforcing plate is attached to a surface opposite to a surface on which the electronic component is mounted in the FPC. Thus, the rigidity of the portion where the electronic component is mounted on the FPC can be increased. Accordingly, even if an external force acts on the FPC due to vibration, contact, or the like, the FPC hardly bends, thereby making it possible to reduce the mechanical stress that is applied to the electronic component, and the joint between the electronic component and the conductor circuit.

However, since the size of the reinforcing plate is large, a certain size is required to attach the reinforcing plate to the FPC. For this reason, when the number of electronic components is small, the workability becomes poor. In addition, when the electronic components are mounted on the FPC in a state in which they are separated from each other, the number of reinforcing plates to be attached to the FPC increases, thereby increasing the manufacturing cost.

Meanwhile, in the present embodiment, with the configuration described above, since the metal plate 40 is provided on the second surface of the coverlay 23 and surrounds the electronic component 10, the rigidity of the portion where the electronic component 10 is mounted on the FPC 20 can be increased. Accordingly, the mechanical stress that is applied to the electronic component 10, and the joint 33 between the electronic component 10 and the conductor circuit 22, can be reduced.

In addition, since the rigidity of the portion where the electronic component 10 is mounted on the FPC 20 can be increased by the metal plate 40, it is not necessary to attach a reinforcing plate to the FPC 20 separately. Since the metal plate 40 can be flexibly machined, it can be made smaller in size than the reinforcing plate. Accordingly, by providing the metal plate 40, the workability can be improved, and an increase in manufacturing cost can be suppressed.

### First Modified Example

In the first embodiment described above, in the opening 24a of the coverlay 23, the joint 33 between the electronic component 10 and the conductor circuit 22 is directly exposed to the outside; however, the present embodiment is not limited thereto. For example, surface treatment may be applied to the opening 24a of the coverlay 23.

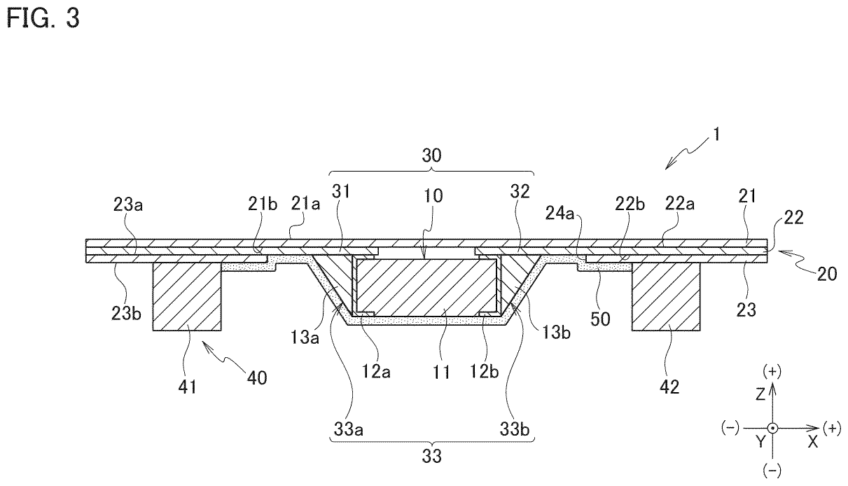

FIG. 3 is an end view of the flexible substrate 1 according to the present modified example. As illustrated in FIG. 3, surface treatment is applied to the opening 24a of the coverlay 23, and the opening 24a is covered with insulating oil 50. Accordingly, in the opening 24a, the joint 33 between the electronic component 10 and the conductor circuit 22 is covered with insulating oil 50, and thus is not directly exposed to the outside.

In the present modified example, the configuration described above makes it possible to increase an insulating property of the joint 33, and a moisture resistance of the joint 33.

### Second Modified Example

In the first embodiment described above, only the electronic component 10 is joined to the conductor circuit 22; however, the present embodiment is not limited thereto. For example, in addition to the electronic component 10, the metal plate 40 may be joined to the conductor circuit 22.

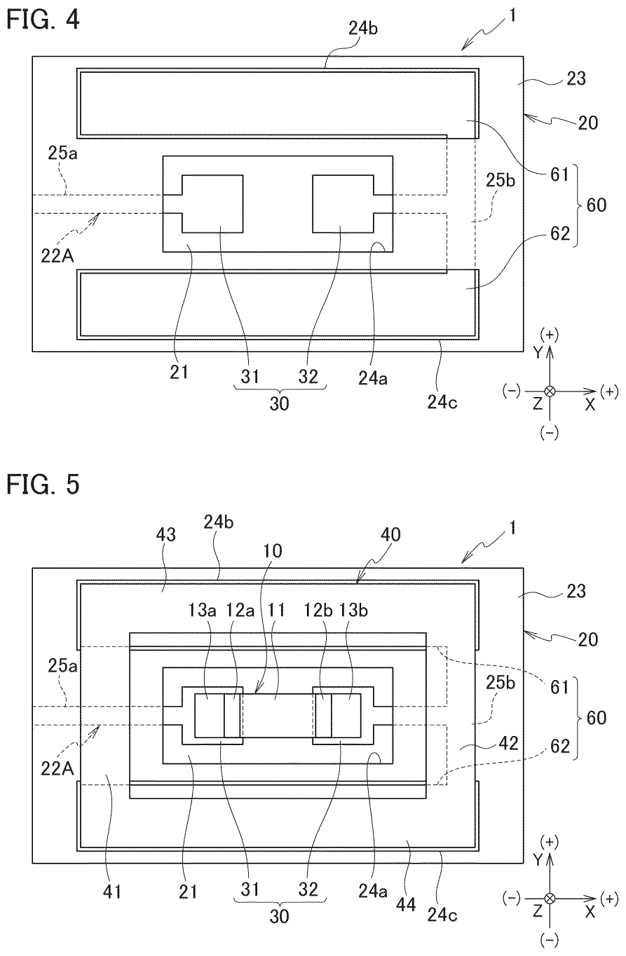

FIG. 4 is a diagram for explaining the state of the flexible substrate 1 according to the present modified example before the electronic component 10 is mounted on the FPC 20. FIG. 5 is a diagram for explaining the state of the flexible substrate 1 according to the present modified example after the electronic component 10 is mounted on the FPC 20.

In the present modified example, in the FPC 20, the conductor circuit 22A is formed on the base film 21 instead of the conductor circuit 22 (see FIG. 4). The conductor circuit 22A includes a first circuit 25a and a second circuit 25b. The first circuit 25a terminates at a pad 31 that forms a −X side end portion of the conductor circuit 22A in the opening 24a.

The second circuit 25b is branched into three branches, and the first branch terminates at a pad 32 that forms a +X side end portion of the conductor circuit 22A in the opening 24a. The second branch terminates at a pad 61 (described later) that forms a +Y side end portion of the conductor circuit 22A in an opening 24b which will be described later. The third branch terminates at a pad 62 (described later) that forms a −Y side end portion of the conductor circuit 22A in an opening 24c which will be described later.

The conductor circuit 22A has a joint region 60 in addition to the joint region 30. The pads 31 and 32 constitute the joint region 30. The electrodes 12a and 12b of the electronic component 10 are joined to the pads 31 and 32, respectively. The pads 61 and 62 constitute the joint region 60. The third portion 43 and the fourth portion 44 of the metal plate 40 are joined to the pads 61 and 62, respectively (see FIG. 5).

The coverlay 23 has the openings 24b and 24c at the portions where the third portion 43 and the fourth portion 44 of the metal plate 40 are provided. In the openings 24b and 24c, the joint region 60 (pads 61, 62) of the conductor circuit 22A to which the third portion 43 and the fourth portion 44 of the metal plate 40 are joined is exposed to the outside. The openings 24b and 24c are also referred to as the second openings. In addition, the joint region 60 is also referred to as the second joint region.

In the present modified example, each of the openings 24b and 24c is formed in a rectangular shape, and a long side and a short side thereof extend along the longitudinal direction and the width direction of the flexible substrate 1, respectively; however, the present embodiment is not limited thereto. Depending on the shape of the joint region 60 of the conductor circuit 22A, each of the openings 24b and 24c may be formed in a shape other than the rectangular shape. Further, even when each of the openings 24b and 24c is formed in the rectangular shape, depending on an arrangement of the joint region 60 of the conductor circuit 22, the long side may extend in a direction other than the longitudinal direction of the flexible substrate 1, and the short side may extend in a direction other than the width direction of the flexible substrate 1.

Since the method for joining the third portion 43 and the fourth portion 44 of the metal plate 40 to the pads 61 and 62, respectively, is the same as the method for joining the electrodes 12a and 12b of the electronic component 10 to the pads 31 and 32, respectively, a description thereof will be omitted.

According to the present modified example, the conductor circuit 22A has the joint region 60 to which a part of the metal plate 40 (the third portion 43 and the fourth portion 44) is joined. The coverlay 23 has the openings 24b and 24c which expose the joint region 60 to the outside.

In the present modified example, for example, when it is necessary to electrically connect the flexible substrate 1 to a portion which is a measurement object, the measurement object can be electrically connected to the conductor circuit 22A of the flexible substrate 1 by joining the metal plate 40 to the measurement object. Thus, when the flexible substrate 1 is electrically connected to the measurement object, there is no need to provide a separate member, thereby further improving the workability and further suppressing an increase in manufacturing cost.

### Second Embodiment

### (Configuration of Flexible Substrate)

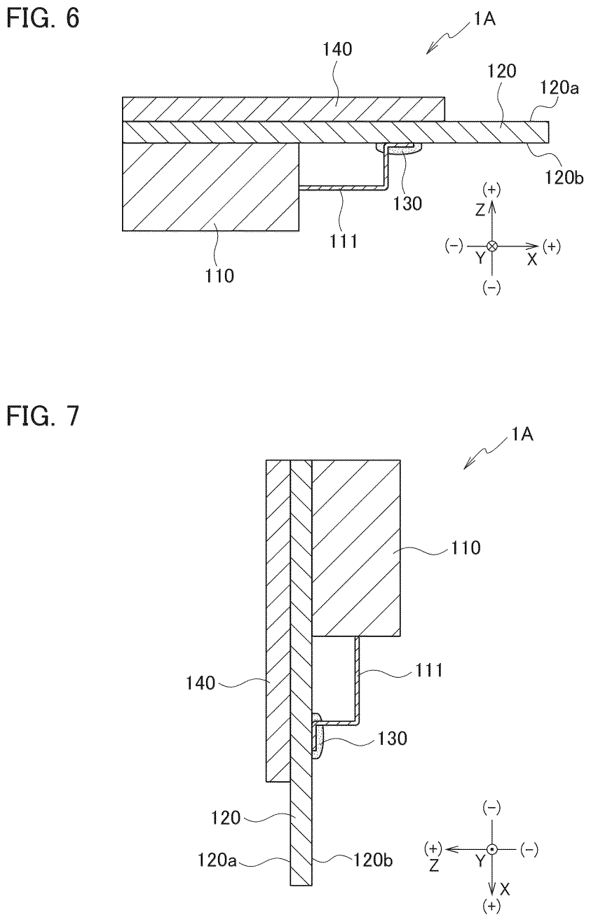

The configuration of a flexible substrate 1A according to the present embodiment will be described below. FIG. 6 is a cross-sectional view of the flexible substrate 1A. In FIG. 6, only a part of the flexible substrate 1A is illustrated in order to clearly indicate the mounting portion of the connector 110.

An X direction illustrated in FIG. 6 corresponds to a longitudinal direction of the flexible substrate 1A. A Y direction illustrated in FIG. 6 corresponds to a width direction of the flexible substrate 1A and is orthogonal to the X direction. A Z direction illustrated in FIG. 6 corresponds to a height direction of the flexible substrate 1A and is orthogonal to the X direction and the Y direction. In the present embodiment, the Z direction corresponds to the vertical direction.

The X direction and the Y direction may correspond to the width direction and the longitudinal direction of the flexible substrate 1A, respectively.

A +X side and a −X side illustrated in FIG. 6 correspond to a front side and a rear side of the flexible substrate 1A, respectively. A +Y side and a −Y side illustrated in FIG. 6 correspond to a left side and a right side of the flexible substrate 1A toward the front side of the flexible substrate 1A, respectively. A +Z side and a −Z side illustrated in FIG. 6 correspond to an upper side and a lower side of the flexible substrate 1A, respectively.

As illustrated in FIG. 6, the flexible substrate 1A includes a connector 110, an FPC 120, a connection portion 130, and a reinforcing plate 140. The flexible substrate 1A includes the connector 110 as an electronic component mounted on the FPC 120.

The connector 110 is provided at an end portion of the FPC 120 in the flexible substrate 1A. The connector 110 is fitted with a mating connector (not illustrated) at an end portion of the FPC 120, thereby electrically connecting the mating connector to the FPC 120.

The connector 110 has a plurality of terminals 111. In FIG. 6, only one terminal 111 is illustrated. One ends of the plurality of terminals 111 are housed in the connector 110, and come into contact with the plurality of terminals of the mating connector when the connector 110 is fitted with the mating connector. The other ends of the plurality of terminals 111 are joined to the FPC 120 using a joint material.

The FPC 120 has the same structure as the FPC 20 in the first embodiment. The FPC 120 has a first surface 120a and a second surface 120b extending in the longitudinal direction of the flexible substrate 1A. The first surface 120a and the second surface 120b face in opposite directions to each other.

In a state in which the flexible substrate 1A is mounted on the product, the first surface 120a and the second surface 120b face upward (+Z side) and downward (−Z side) in the flexible substrate 1A, respectively (see FIGS. 1 and 2). For this reason, the first surface 120a and the second surface 120b are also referred to as the upper side surface in the vertical direction and the lower side surface in the vertical direction, respectively.

The first surface 120a of the FPC 120 corresponds to one surface of the base film of the FPC 120. The second surface 120b of the FPC 120 corresponds to one surface of the coverlay of the FPC 120.

The connector 110 is mounted on the second surface 120b of the FPC 120. An opening is formed in the second surface 120b of the FPC 120, and a joint region of a conductor circuit of the FPC 120 is exposed to the outside in the opening. The other ends of the plurality of terminals 111 of the connector 110 are joined to the joint region of the conductor circuit of the FPC 120 in the opening of the second surface 120b. The joint region of the conductor circuit is constituted of the pads of the conductor circuit as in the first embodiment.

Since the method for joining the other ends of the plurality of terminals 111 of the connector 110 to the pads of the conductor circuit of the FPC 120 is the same as the method for joining the electrodes 12a and 12b of the electronic component 10 to the pads 31 and 32, respectively, in the first embodiment, a description thereof will be omitted.

The connection portion 130 is made of a joint material accumulated on the other ends of the plurality of terminals 111 of the connector 110. The plurality of terminals 111 of the connector 110 are electrically connected to the joint region of the conductor circuit of the FPC 120 by the connection portion 130.

The other ends of the plurality of terminals 111 of the connector 110, the connection portion 130 (joint material), and the joint region of the conductor circuit of the FPC 120 constitute the joint between the connector 110 and the conductor circuit of the FPC 120.

The reinforcing plate 140 is attached to the first surface 120a of the FPC 120. As viewed from a plane orthogonal to the height direction of the flexible substrate 1 (X-Y plane), the region provided with the reinforcing plate 140 includes the region provided with the connector 110. As a result, the reinforcing plate 140 can increase the rigidity of the region where the connector 110 is mounted on the FPC 120.

In the present embodiment, the connector 110 is provided at the end portion of the FPC 120, and fitted with the mating connector (not illustrated). Thus, since the connector 110 cannot be surrounded by a metal plate, the reinforcing plate 140 is used to increase the rigidity of the portion where the connector 110 is mounted on the FPC 120.

### Action and Effect

According to the present embodiment, the flexible substrate 1A includes the connector 110 and the FPC 120. The connector 110 has the plurality of terminals 111. The FPC 120 has the joint region to which the plurality of terminals 111 are joined using a joint material. The second surface 120b (the lower side surface in the vertical direction) of the FPC 120 has the opening for exposing the joint region to the outside.

In the present embodiment, with the configuration described above, the other ends of the plurality of terminals 111 of the connector 110, the connection portion 130 (the joint material), and the joint region of the conductor circuit of the FPC 120, which are included in the joint between the connector 110 and the conductor circuit of the FPC 120, are arranged on the second surface 120b side of the FPC 120. Here, the second surface 120b of the FPC 120 faces the lower side in the vertical direction.

For this reason, even when dew condensation occurs in the opening of the second surface 120b of the FPC 120, dew condensation water drains to the lower side in the vertical direction (the ground side). Thus, with a simple configuration, it is possible to prevent the dew condensation water from accumulating in the joint between the connector 110 and the conductor circuit of the FPC 120, thereby reliably avoiding a short circuit between the terminals 111 of the connector 110. Accordingly, it is possible to increase a moisture resistance of the joint between the connector 110 and the conductor circuit of the FPC 120 while suppressing a reduction in yield at the time of manufacturing. In addition, it is possible to prevent foreign matter from adhering to the second surface 120b of the FPC 120.

### Modified Example

In the second embodiment described above, in a state in which the flexible substrate 1A is mounted on the product, the first surface 120a and the second surface 120b of the FPC 120 face the upper side in the vertical direction and the lower side in the vertical direction, respectively; however, the present embodiment is not limited thereto. For example, the flexible substrate 1A may be raised in such a way that the connector 110 is positioned at the upper end, and each of the first surface 120a and the second surface 120b may face the direction perpendicular to the vertical direction.

FIG. 7 is a cross-sectional view of the flexible substrate 1A according to the present modified example. In the present modified example, since the flexible substrate 1A is raised in such a way that the connector 110 is positioned at the upper end, the X direction corresponds to the vertical direction.

As illustrated in FIG. 7, when the flexible substrate 1A is mounted on the product, each of the first surface 120a and the second surface 120b of the FPC 120 faces the direction perpendicular to the vertical direction.

With this configuration, even when dew condensation occurs in the opening of the second surface 120b of the FPC 120, dew condensation water drains to the lower side in the vertical direction (+X side, ground side). Thus, with a simple configuration, it is possible to prevent the dew condensation water from accumulating in the joint between the connector 110 and the conductor circuit of the FPC 120, and to reliably avoid a short circuit between the terminals 111 of the connector 110. In addition, it is possible to prevent foreign matter from adhering to the second surface 120b of the FPC 120.

### Third Embodiment

### (Overall Configuration of Bus Bar Module)

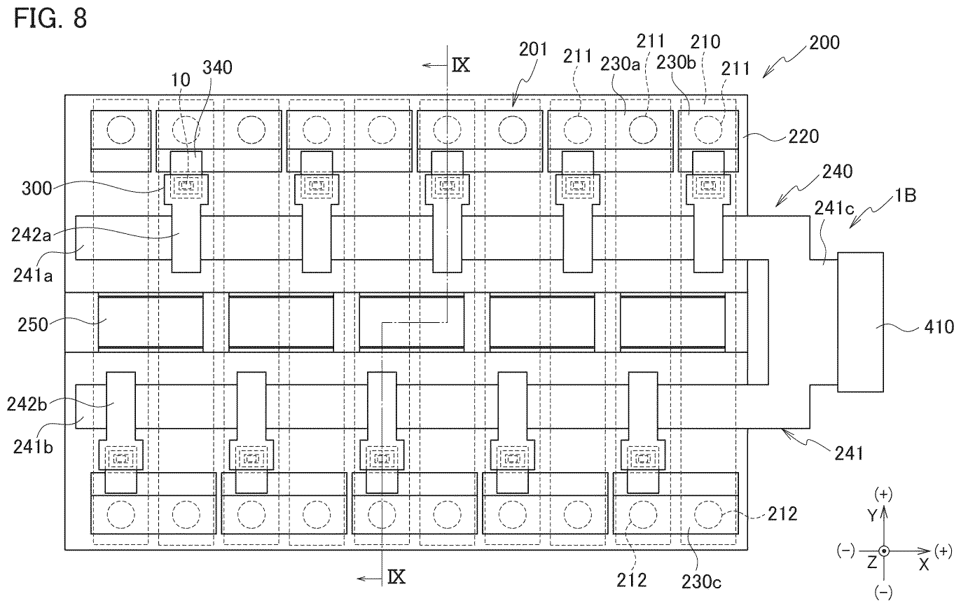

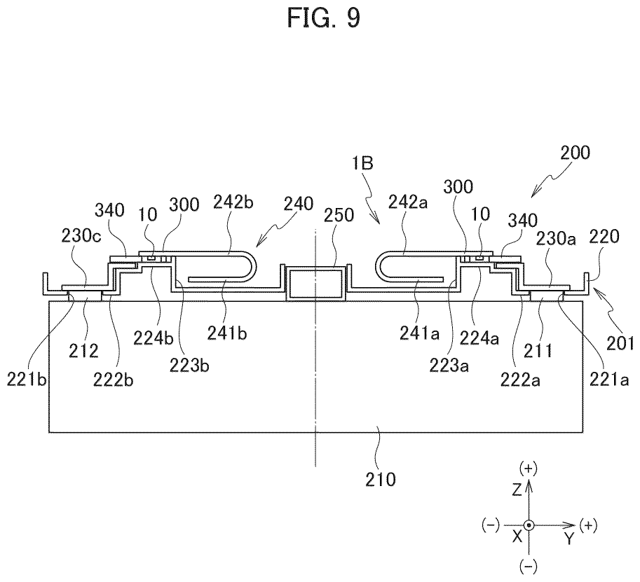

First, the configuration of a bus bar module 201 including a flexible substrate 1B according to the present embodiment will be described. FIG. 8 is a plan view of the bus bar module 201. FIG. 9 is a cross-sectional view along line IX-IX of FIG. 8. Note that hatching is not illustrated in FIG. 9.

An X direction illustrated in FIGS. 8 and 9 corresponds to a longitudinal direction of the flexible substrate 1B. A Y direction illustrated in FIGS. 8 and 9 corresponds to a width direction of the flexible substrate 1B and is orthogonal to the X direction. A Z direction illustrated in FIGS. 8 and 9 corresponds to a height direction of the flexible substrate 1B and is orthogonal to the X direction and the Y direction. In the present embodiment, the Z direction corresponds to the vertical direction.

A +X side and a −X side illustrated in FIGS. 8 and 9 correspond to a front side and a rear side of the flexible substrate 1B, respectively. A +Y side and a −Y side illustrated in FIGS. 8 and 9 correspond to a left side and a right side of the flexible substrate 1B toward the front side of the flexible substrate 1B, respectively. A +Z side and a −Z side illustrated in FIGS. 8 and 9 correspond to an upper side and a lower side of the flexible substrate 1B, respectively.

As illustrated in FIG. 8, the bus bar module 201 is included in a cell module 200, and is assembled to an upper part of a plurality of single cells 210. The cell module 200 is mounted as a power source in a vehicle such as an electric vehicle. The electric vehicle includes, for example, a battery electric vehicle, a hybrid electric vehicle, and a plug-in hybrid electric vehicle.

The cell module 200 includes the bus bar module 201, the plurality of single cells 210, and a flue gas duct 250. Hereinafter, the plurality of single cells 210, the flue gas duct 250, and the bus bar module 201 will be described in order for the sake of convenience.

In the cell module 200, the plurality of single cells 210 are arranged along the longitudinal direction of the flexible substrate 1B. Thus, the longitudinal direction of the flexible substrate 1B corresponds to an arrangement direction of the single cells 210. Although ten single cells 210 are illustrated in FIG. 8, the number of single cells 210 is not limited thereto, and may be from two to nine, or eleven or more.

Each single cell 210 is, for example, a lithium-ion cell. Electrode terminals 211 and 212 are provided to project from the upper surfaces of both ends of each single cell 210. One of the electrode terminals 211 and 212 is a positive electrode, and the other of the electrode terminals 211 and 212 is a negative electrode.

In a state in which the plurality of single cells 210 are arranged, the plurality of electrode terminals 211 are arranged on the +Y side to form a first electrode terminal group. In the first electrode terminal group, electrode terminals 211, which are positive electrodes, and electrode terminals 211, which are negative electrodes, are arranged alternately. Thus, in the adjacent single cells 210, one of two electrode terminals 211 is a positive electrode, and the other thereof is a negative electrode.

Similarly, when the plurality of single cells 210 are arranged, the plurality of electrode terminals 212 are arranged on the −Y side to form a second electrode terminal group. In the second electrode terminal group, electrode terminals 212, which are positive electrodes, and electrode terminals 212, which are negative electrodes, are arranged alternately. Thus, in the adjacent single cells 210, one of two electrode terminals 212 is a positive electrode, and the other thereof is a negative electrode.

The flue gas duct 250 is a tube for discharging gas, which is discharged to the outside when a gas pressure in each single cell 210 exceeds a predetermined value, to the outside of the cell module 200. The flue gas duct 250 extends along the arrangement direction of the single cells 210, and is placed on the upper surface between the electrode terminals 211 and 212 in each single cell 210.

The bus bar module 201 includes the flexible substrate 1B, a case 220, and a plurality of bus bars 230a to 230c. The plurality of bus bars 230a to 230c, the flexible substrate 1B, and the case 220 will be described in this order for the sake of convenience.

Each of the plurality of bus bars 230a to 230c is made of a conductive metal material, and is formed in a plate shape. The plurality of bus bars 230a and 230b are arranged on the +Y side with respect to the flue gas duct 250. The plurality of bus bars 230c are arranged on the −Y side with respect to the flue gas duct 250. In the present embodiment, the number of bus bars 230a is four, the number of bus bars 230b is two, and the number of bus bars 230c is five according to the number of single cells 210 (ten).

Each bus bar 230a is connected to adjacent electrode terminals 211 by welding or the like in the first electrode terminal group. In the case of the first electrode terminal group, the adjacent electrode terminals 211 do not include two electrode terminals 211 arranged at both ends thereof. As a result, the adjacent electrode terminals 211 are electrically connected to each other via the bus bar 230a.

Each bus bar 230b is connected to the electrode terminal 211 arranged at both ends of the first electrode terminal group by welding or the like.

Each bus bar 230c is connected to the adjacent electrode terminals 212 by welding or the like in the second electrode terminal group. Thus, the adjacent electrode terminals 212 are electrically connected to each other via the bus bar 230c.

With this configuration, in the cell module 200, the plurality of single cells 210 are electrically connected in series to form a cell pack.

The flexible substrate 1B includes an FPC 240. The FPC 240 has a trunk portion 241, and a plurality of branch portions 242a and 242b. The trunk portion 241 is formed in a substantially U-shape, and has a first extension portion 241a, a second extension portion 241b, and a coupling portion 241c.

The first extension portion 241a is arranged on the +Y side with respect to the flue gas duct 250, and extends along the longitudinal direction of the flexible substrate 1B. The second extension portion 241b is arranged on the −Y side with respect to the flue gas duct 250, and extends along the longitudinal direction of the flexible substrate 1B. Thus, the second extension portion 241b extends in parallel with the first extension portion 241a.

The coupling portion 241c couples a +X side end portion of the first extension portion 241a and a +X side end portion of the second extension portion 241b at a −X side end portion of the coupling portion 241c. A connector 410 is mounted on a +X side end portion of the coupling portion 241c.

Each of the plurality of branch portions 242a branches in a direction approaching the second extension portion 241b from the first extension portion 241a of the trunk portion 241 and then is folded back in a direction away from the second extension portion 241b so as to intersect with the first extension portion 241a in a plan view (X-Y plan view). Specifically, each of the plurality of branch portions 242a branches from a lateral part of the first extension portion 241a of the trunk portion 241 on the −Y side and then is folded back so as to intersect with the first extension portion 241a in a plan view (X-Y plan view) (see FIG. 9).

Similarly, each of the plurality of branch portions 242b branches in a direction approaching the first extension portion 241a from the second extension portion 241b of the trunk portion 241 and then is folded back in a direction away from the first extension portion 241a so as to intersect with the second extension portion 241b in a plan view (X-Y plan view). Specifically, each of the plurality of branch portions 242b branches from a lateral part of the second extension portion 241b of the trunk portion 241 on the +Y side and then is folded back so as to intersect with the second extension portion 241b in a plan view (X-Y plan view) (see FIG. 9).

The electronic component 10 and the metal plate 340 are mounted on an end portion 300 of each folded-back branch portion 242a (+Y side), as will be described later. The end portion 300 of each folded-back branch portion 242a is electrically connected to the bus bar 230a or the bus bar 230b, which is arranged on the +Y side with respect to the flue gas duct 250, via the metal plate 340.

Similarly, the electronic component 10 and the metal plate 340 are mounted on an end portion 300 (−Y side) of each folded-back branch portion 242b, as will be described later. The end portion 300 of each folded-back branch portion 242b is electrically connected to the bus bar 230c, which is arranged on the −Y side with respect to the flue gas duct 250, via the metal plate 340.

As illustrated in FIG. 8, the case 220 is assembled to an upper part of the plurality of single cells 210. As illustrated in FIG. 9, the case 220 has a plurality of terminal insertion holes 221a, a bus bar support 222a, a trunk housing section 223a, and a branch support 224a on the +Y side with respect to the flue gas duct 250. In FIG. 9, only one terminal insertion hole 221a is illustrated.

The plurality of electrode terminals 211 are inserted into the plurality of terminal insertion holes 221a, respectively. The bus bar support 222a, the trunk housing section 223a, and the branch support 224a extend along the arrangement direction of the single cells 210. The bus bar support 222a supports a plurality of bus bars 230a and 230b. The trunk housing section 223a houses the first extension portion 241a of the trunk portion 241 of the FPC 240. The branch support 224a supports the branch portion 242a of the FPC 240.

Similarly, the case 220 has a plurality of terminal insertion holes 221b, a bus bar support 222b, a trunk housing section 223b, and a branch support 224b on the −Y side with respect to the flue gas duct 250. In FIG. 9, only one terminal insertion hole 221b is illustrated.

A plurality of electrode terminals 212 are inserted into the plurality of terminal insertion holes 221b, respectively. The bus bar support 222b, the trunk housing section 223b, and the branch support 224b extend along the arrangement direction of the single cells 210. The bus bar support 222b supports a plurality of bus bars 230c. The trunk housing section 223b houses the second extension portion 241b of the trunk portion 241 of the FPC 240. The branch support 224b supports the branch portion 242b of the FPC 240.

In the present embodiment, a length of each folded-back branch portion 242a is greater than a width of the first extension portion 241a of the trunk portion 241 (see FIG. 9); however, the present embodiment is not limited thereto. The length of each folded-back branch portion 242a may be less than the width of the first extension portion 241a of the trunk portion 241. In this case, the branch support 224a is arranged in a position where each folded-back branch portion 242a can be supported.

Similarly, a length of each folded-back branch portion 242b is greater than a width of the second extension portion 241b of the trunk portion 241 (see FIG. 9); however, the present embodiment is not limited thereto. The length of each folded-back branch portion 242b may be less than the width of the second extension portion 241b of the trunk portion 241. In this case, the branch support 224b is arranged in a position where each folded-back branch portion 242b can be supported.

### (Configuration of Flexible Substrate)

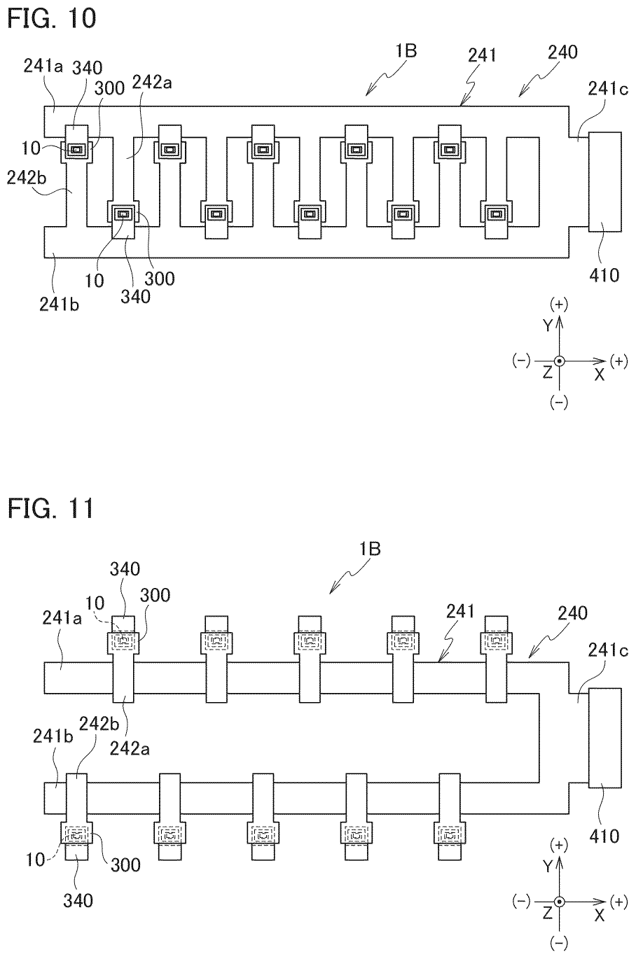

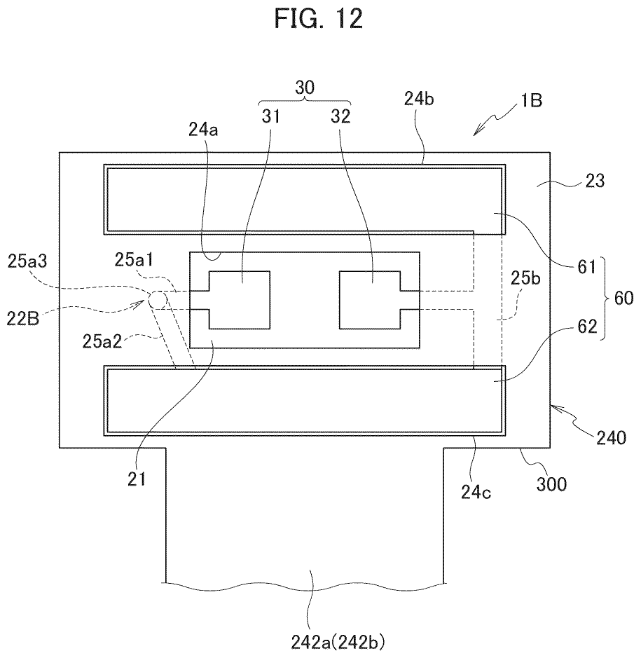

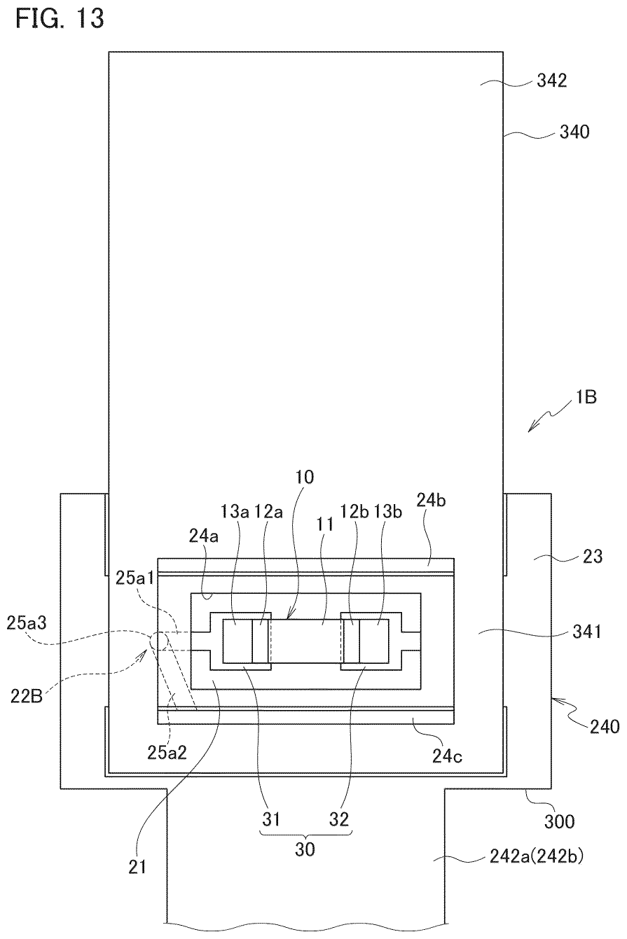

Next, a configuration of the flexible substrate 1B will be described. FIG. 10 is a diagram for explaining a state of the flexible substrate 1B before folding back the plurality of branch portions 242a and 242b branched from the trunk portion 241 of the FPC 240. FIG. 11 is a diagram for explaining a state of the flexible substrate 1B after folding back the plurality of branch portions 242a and 242b branched from the trunk portion 241 of the FPC 240. FIG. 12 is a diagram for explaining a state of the flexible substrate 1B before mounting the electronic component 10 on the end portion 300 of the branch portion 242a or the branch portion 242b of the FPC 240. FIG. 13 is a diagram for explaining a state of the flexible substrate 1B after mounting the electronic component 10 on the end portion 300 of the branch portion 242a or the branch portion 242b of the FPC 240.

The flexible substrate 1B includes a plurality of electronic components 10, the FPC 240, a plurality of metal plates 340, and the connector 410. The plurality of electronic components 10 and the plurality of metal plates 340 are mounted on the end portions 300 of the plurality of branch portions 242a and 242b in the FPC 240, as described above. A configuration of the end portion 300 of each branch portion will be described later.

As described above, the FPC 240 has the trunk portion 241, and the plurality of branches portions 242a and 242b. The trunk portion 241 has the first extension portion 241a, the second extension portion 241b, and the coupling portion 241c.

In the present embodiment, the FPC 240 includes the base film 21, a plurality of conductor circuits 22B, and the coverlay 23. The base film 21 is a base material of the FPC 240, and defines the overall shape of the FPC 240.

The plurality of conductor circuits 22B are formed on the second surface 21b of the base film 21. Each of the plurality of conductor circuits 22B has one end that is electrically connected to the metal plate 340 mounted on the end portion 300 of each branch portion via the electronic component 10, and the other end that is electrically connected to the connector 410 mounted on the trunk portion 241. As described above, each metal plate 340 is electrically connected to each bus bar.

In the present embodiment, each conductor circuit 22B functions as a voltage detection line. For example, an ECU (Electric Control Unit) (not illustrated) is connected to the connector 410. The ECU can detect a voltage of each single cell 210 by acquiring the voltage from the plurality of conductor circuits 22B.

Except for one region of the second surface 21b of the base film 21 and one region (joint regions 30 and 60) of the second surface 22b of the conductor circuit 22, which are exposed to the outside in the openings 24a to 24c at the end portion 300 of each branch portion, the coverlay 23 covers the second surface 21b of the base film 21 and the second surface 22b of the conductor circuit 22 (see FIG. 12). Thus, the coverlay 23 is stacked on a part of the base film 21 and a part of the conductor circuit 22 on the second surface 21b side of the base film 21 and the second surface 22b side of the conductor circuit 22.

Next, a description will be given in which the plurality of branch portions 242a and 242b are folded back in the FPC 240.

As illustrated in FIG. 10, in a state before folding back the plurality of branch portions 242a, each of the plurality of branch portions 242a branches from the first extension portion 241a of the trunk portion 241 and extends in a direction approaching the second extension portion 241b. Specifically, each of the plurality of branch portions 242a branches from the lateral part of the first extension portion 241a of the trunk portion 241 on the −Y side and extends in the −Y side along the width direction of the flexible substrate 1B. In this state, the electronic component 10 and the metal plate 340 are mounted on the end portion 300 of each branch portion 242a.

Similarly, in a state before folding back the plurality of branch portions 242b, each of the plurality of branch portions 242b branches from the second extension portion 241b of the trunk portion 241 and extends in a direction approaching the first extension portion 241a. Specifically, each of the plurality of branch portions 242b branches from the lateral part of the second extension portion 241b of the trunk portion 241 on the +Y side and extends in the +Y side along the width direction of the flexible substrate 1B. In this state, the electronic component 10 and the metal plate 340 are mounted on the end portion 300 of each branch portion 242b.

As illustrated in FIG. 11, in a state in which the electronic component 10 and the metal plate 340 are mounted on the end portion 300 of each branch portion 242a, each of the plurality of branch portions 242a is folded back in a direction away from the second extension portion 241b so as to intersect with the first extension portion 241a in a plan view (X-Y plan view).

Similarly, in a state in which the electronic component 10 and the metal plate 340 are mounted on the end portion 300 of each branch portion 242b, each of the plurality of branch portions 242b is folded back in a direction away from the first extension portion 241a so as to intersect with the second extension portion 241b in a plan view (X-Y plan view).

After folding back the plurality of branch portions 242a and 242b, the FPC 240 is assembled to the case 220, and electrically connected to the plurality of bus bars 230a to 230c via the plurality of metal plates 340 (see FIG. 9).

Next, configurations of the end portions 300 of the plurality of branch portions 242a and 242b in the FPC 240 will be described. The configuration of the end portion 300 of each branch portion in the FPC 240 is the same as that of the FPC 20 according to the second modified example of the first embodiment (see FIG. 4), except for the conductor circuit 22B and the metal plate 340. In the FPC 240, a longitudinal direction (Y direction) and a width direction (X direction) of each branch portion correspond to the width direction (Y direction) and the longitudinal direction (X direction) of the FPC 20 according to the second modified example of the first embodiment, respectively.

In the present embodiment, as illustrated in FIG. 12, in the FPC 20, the conductor circuit 22B is formed on the base film 21 instead of the conductor circuit 22. The conductor circuit 22B has a first circuit 25al, an auxiliary circuit 25a2, and a second circuit 25b.

A configuration of the first circuit 25al is the same as that of the first circuit 25a according to the second modified example of the first embodiment, except that it is electrically connected to the auxiliary circuit 25a2 formed on the first surface 21a of the base film 21 via a via hole 25a3.

On the first surface 21a side of the base film 21, an insulating coverlay (not illustrated) is provided separately to cover at least the auxiliary circuit 25a2. When extended for a predetermined length, the auxiliary circuit 25a2 is electrically connected to a circuit (not illustrated) of the conductor circuit 22B formed on the second surface 21b of the base film 21 via a via hole (not illustrated).

A configuration of the second circuit unit 25b is the same as that of the second circuit unit 25b according to the second modified example of the first embodiment, and thus a description thereof will be omitted.

As illustrated in FIG. 13, the opening 24a is surrounded by the metal plate 340 provided in the coverlay 23 at one end 341 of the metal plate 340. For this reason, the electronic component 10 is surrounded by the metal plate 340. The metal plate 340 is joined to the joint region 60 (pads 61, 62) of the conductor circuit 22B using a joint material.

The metal plate 340 extends from the end portion 300 of each branch portion along the longitudinal direction of the branch portion for a predetermined length. The metal plate 340 is joined to each bus bar by welding or the like at the other end 342 of the metal plate 340 (see FIG. 9). With this configuration, the electronic component 10 is electrically connected to each bus bar via the second circuit 25b of the conductor circuit 22B and the metal plate 340.

In the present embodiment, the rigidity of the end portion 300 of each branch portion can be increased by providing the metal plate 340, and thus no reinforcing plate is provided on the first surface 21a of the base film 21 in the end portion 300.

### Action and Effect

According to the present embodiment, the flexible substrate 1B is included in the bus bar module 201. The bus bar module 201 has the plurality of bus bars 230a each of which electrically connects the positive and negative electrode terminals 211 and 211 of the adjacent single cells 210 and 210, and the plurality of bus bars 230c each of which electrically connects the positive and negative electrode terminals 212 and 212 of the adjacent single cells 210 and 210. The metal plate 340 is joined to one bus bar among the bus bars 230a and 230c. The electronic component 10 is electrically connected to the one bus bar via the conductor circuit 22B and the metal plate 340.

In the present embodiment, with the configuration described above, the bus bar can be electrically connected to the conductor circuit 22B by joining the metal plate 340 to the bus bar. Thus, when the conductor circuit 22B is electrically connected to the bus bar, there is no need to provide a separate member, thereby further improving the workability, and further suppressing an increase in manufacturing cost.

According to the present embodiment, the flexible substrate 1B includes the trunk portion 241, and the plurality of branch portions 242a and 242b branching from the trunk portion 241. Each of the branch portions 242a and 242b is folded back so as to intersect with the trunk portion 241 in a plan view. The end portion 300 of each of the branch portions 242a and 242b has the electronic component 10, the base film 21, the conductor circuit 22B, the coverlay 23, and the metal plate 340.

In the present embodiment, with the configuration described above, since each of the branch portions 242a and 242b is folded back so as to intersect with the trunk portion 241 in a plan view, the amount of projection of each branch portion in the width direction of the flexible substrate 1B (the spreading of each branch portion in the width direction of the flexible substrate 1B) can be reduced, and the length of each branch portion can be secured. Thus, even when a thermal expansion occurs in the cell module 200, a tolerance is easily absorbed in each branch portion.

According to the present embodiment, the trunk portion 241 is formed in a substantially U-shape, and has the first extension portion 241a, the second extension portion 241b, and the coupling portion 241c. The second extension portion 241b extends in parallel with the first extension portion 241a. The coupling portion 241c couples the end portion of the first extension portion 241a and the end portion of the second extension portion 241b.

When each of the plurality of branch portions 242a branches in a direction approaching the second extension portion 241b from the first extension portion 241a, each of the branch portions 242a is folded back in a direction away from the second extension portion 241b so as to intersect with the first extension portion 241a in a plan view. When each of the plurality of branch portions 242b branches in a direction approaching the first extension portion 241a from the second extension portion 241b, each of the branch portions 242b is folded back in a direction away from the first extension portion 241a so as to intersect with the second extension portion 241b in a plan view.

In the present embodiment, with the configuration described above, the plurality of branch portions 242a branch from the first extension portion 241a in a direction approaching the second extension portion 241b. Thus, as compared with the case in which the plurality of branch portions 242a branch from the first extension portion 241a in a direction away from the second extension portion 241b, it is possible to reduce the number of regions in the FPC 240 that are not used as the branch portions, thereby reducing the amount of waste material.

Similarly, the plurality of branch portions 242b branch from the second extension portion 241b in a direction approaching the first extension portion 241a. Thus, as compared with the case in which the plurality of branch portions 242b branch from the second extension portion 241b in a direction away from the first extension portion 241a, it is possible to reduce the number of regions in the FPC 240 that are not used as the branch portions, thereby reducing the amount of waste material.

According to the present embodiment, the bus bar module 201 includes the case 220, the plurality of bus bars 230a and 230c, and the FPC 240. The case 220 is assembled to the cell module 200 having a plurality of single cells 210. Each of the plurality of bus bars 230a is supported by the case 220, and electrically connects the positive and negative electrode terminals 211 and 211 of the adjacent single cells 210 and 210 among the plurality of single cells 210. Each of the plurality of bus bars 230c is supported by the case 220, and electrically connects the positive and negative electrode terminals 212 and 212 of the adjacent single cells 210 and 210 among the plurality of single cells 210. The FPC 240 is housed in the case 220.

The FPC 240 includes the trunk portion 241, and the plurality of branch portions 242a and 242b branching from the trunk portion 241. The plurality of branch portions 242a and 242b are folded back so as to intersect with the trunk portion 241 in a plan view, and are electrically connected to the plurality of bus bars 230a and 230c, respectively.

Each of the end portions 300 of the branch portions 242a and 242b has the electronic component 10, the base film 21, the conductor circuit 22B, the coverlay 23, and the metal plate 340. The electronic component 10 has electrodes 12a and 12b. The conductor circuit 22B is formed on the second surface (the lower side surface in the vertical direction) 21b of the base film 21, and has the joint region 30 and the joint region 60. The coverlay 23 covers at least a part of the second surface (the lower side surface in the vertical direction) 22b of the conductor circuit 22B, and has the openings 24a to 24c. The opening 24a exposes the joint region 30 to the outside. The openings 24b and 24c expose the joint region 60 to the outside. The metal plate 340 is provided on the second surface (the lower side surface in the vertical direction) 23b of the coverlay 23, and surrounds the electronic component 10.

In the opening 24a, the electrodes 12a and 12b are joined to the joint region 30 using a joint material. In the openings 24b and 24c, one end 341 of the metal plate 340 is joined to the joint region 60. The other end 342 of the metal plate 340 is joined to each of the plurality of bus bars 230a and 230c. The electronic component 10 is electrically connected to each of the plurality of bus bars 230a and 230c via the conductor circuit 22B and the metal plate 340.

In the present embodiment, with the configuration described above, the electrodes 12a and 12b of the electronic component 10, the joint material, and the joint region 30 of the conductor circuit 22B, which are included in the joint 33 between the electronic component 10 and the conductor circuit 22B, are arranged on the second surface 21b of the base film 21. Here, the second surface 21b of the base film 21 faces the lower side in the vertical direction.

For this reason, even when dew condensation occurs in the opening 24a of each branch portion of the FPC 240, dew condensation water drains to the lower side in the vertical direction (the ground side). Thus, with a simple configuration, it is possible to prevent the dew condensation water from accumulating in the joint 33, thereby reliably avoiding a short circuit of the electronic component 10. Accordingly, in the bus bar module 201, it is possible to increase a moisture resistance of the joint 33 between the electronic component 10 and the conductor circuit 22 while suppressing a reduction in yield at the time of manufacturing.

With the configuration described above, the bus bar can be electrically connected to the conductor circuit 22B by joining the metal plate 340 to the bus bar. Thus, when the conductor circuit 22B is electrically connected to the bus bar, there is no need to provide a separate member, thereby further improving the workability, and further suppressing an increase in manufacturing cost.

With the configuration described above, since each of the plurality of branch portions 242a and 242b is folded back so as to intersect with the trunk portion 241 in a plan view, the amount of projection of each branch portion in the width direction of the flexible substrate 1B (the spreading of each branch portion in the width direction of the flexible substrate 1B) can be reduced, and the length of each branch portion can be secured. Thus, even when a thermal expansion occurs in the cell module 200, a tolerance is easily absorbed in each branch portion.

### Modified Example

In the third embodiment described above, the trunk portion 241 of the FPC 240 is formed in a substantially U-shape because the flue gas duct 250 is placed on the upper surface between the electrode terminals 211 and 212 in each single cell 210; however, the present embodiment is not limited thereto. For example, if the flue gas duct 250 is not placed on the upper surface between the electrode terminals 211 and 212 in each single cell 210, the trunk portion may be formed linearly.

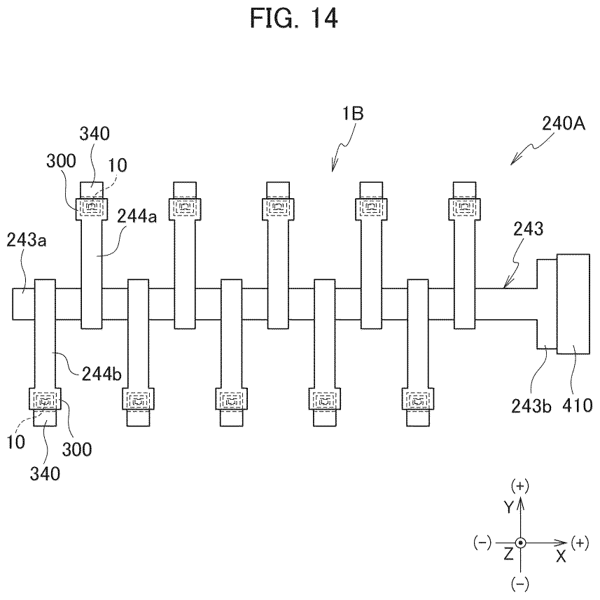

FIG. 14 is a plan view of a flexible substrate 1B according to the present modified example. As illustrated in FIG. 14, the flexible substrate 1B includes an FPC 240A. The FPC 240A has a trunk portion 243, and a plurality of branch portions 244a and 244b. The trunk portion 243 is formed linearly, and has an extension portion 243a and a coupling portion 243b.

The extension portion 243a extends along the longitudinal direction of the flexible substrate 1B. The coupling portion 243b is coupled to a +X side end portion of the extension portion 243a at a −X side end portion of the coupling portion 243b, and a connector 410 is mounted on a +X side end portion of the coupling portion 243b.

Each of the plurality of branch portions 244a branches from one side (−Y side) of the extension portion 243a, and then is folded back toward the +Y side so as to intersect with the extension portion 243a in a plan view (X-Y plan view). Similarly, each of the plurality of branch portions 244b branches from the other side (+Y side) of the extension portion 243a, and then is folded back toward the −Y side so as to intersect with the extension portion 243a in the plan view (X-Y plan view). The branch portions 244a and 244b are alternately provided along the longitudinal direction of the flexible substrate 1B.

If the flexible substrate 1B can be assembled to the upper side of the flue gas duct 250, the trunk portion can be formed linearly even if the flue gas duct 250 is placed on the upper surface between the electrode terminals 211 and 212 in each single cell 210.

With the configuration described above, since each of the plurality of the branch portions 244a and 244b is folded back so as to intersect with the trunk portion 243 in a plan view, the amount of projection of each branch portion in the width direction of the flexible substrate 1B (the spreading of each branch portion in the width direction of the flexible substrate 1B) can be reduced, and the length of each branch portion can be secured. Thus, even when a thermal expansion occurs in the cell module 200, a tolerance is easily absorbed in each branch portion.

### Other Modified Examples

Two or more of the first embodiment, the first and second modified examples of the first embodiment, the second embodiment, the modified example of the second embodiment, the third embodiment, and the modified example of the third embodiment may be combined and applied to a flexible substrate and a bus bar module.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A flexible substrate comprising:
an electronic component that has an electrode;
a base film;
a conductor circuit that is formed on a lower side surface of the base film in a vertical direction, and has a first joint region to which the electrode is jointed using a joint material; and
a coverlay that covers at least a part of a lower side surface of the conductor circuit in the vertical direction, and has a first opening exposing the first joint region to an outside.

2. The flexible substrate according to claim 1, wherein the first opening is covered with insulating oil.

3. The flexible substrate according to claim 1, further comprising a metal plate, wherein
the coverlay further covers a part of a lower side surface of the base film in the vertical direction, except for a region exposed to the outside in the first opening,
the metal plate is provided on a lower side surface of the coverlay in the vertical direction, and surrounds the electronic component, and
a reinforcing plate is not provided on an upper side surface of the base film in the vertical direction.

4. The flexible substrate according to claim 3, wherein
the conductor circuit has a second joint region to which a part of the metal plate is jointed, and
the coverlay has a second opening exposing the second joint region to the outside.

5. The flexible substrate according to claim 4, wherein
the flexible substrate is included in a bus bar module having a plurality of bus bars each of which electrically connects positive and negative electrode terminals of adjacent single cells,
the metal plate is joined to one bus bar among the plurality of bus bars, and
the electronic component is electrically connected to the one bus bar via the conductor circuit and the metal plate.

6. The flexible substrate according to claim 5, further comprising:
a trunk portion; and
a branch portion branching from the trunk portion, wherein
the branch portion is folded back so as to intersect with the trunk portion in a plan view, and
an end portion of the branch portion has the electronic component, the base film, the conductor circuit, the coverlay, and the metal plate.

7. The flexible substrate according to claim 6, wherein
the trunk portion is formed in a substantially U-shape, and has a first extension portion, a second extension portion extending in parallel with the first extension portion, and a coupling portion which couples an end portion of the first extension portion and an end portion of the second extension portion,
when the branch portion branches in a direction approaching the second extension portion from the first extension portion, the branch portion is folded back in a direction away from the second extension portion so as to intersect with the first extension portion in a plan view, and
when the branch portion branches in a direction approaching the first extension portion from the second extension portion, the branch portions is folded back in a direction away from the first extension portion so as to intersect with the second extension portion in a plan view.

8. A bus bar module comprising:
a case that is assembled to a cell module having a plurality of single cells;
a bus bar that is supported by the case, and electrically connects positive and negative electrode terminals of adjacent single cells among the plurality of single cells; and
a flexible substrate that is housed in the case, wherein
the flexible substrate has:
a trunk portion; and
a branch portion that branches from the trunk portion, is folded back so as to intersect with the trunk portion in a plan view, and is electrically connected to the bus bar, and
an end portion of the branch portion has:
an electronic component that has an electrode;
a base film;
a conductor circuit that is formed on a lower side surface of the base film in a vertical direction, and has a first joint region and a second joint region;
a coverlay that covers at least a part of a lower side surface of the conductor circuit in the vertical direction, and has a first opening exposing the first joint region to an outside and a second opening exposing the second joint region to the outside; and
a metal plate, and
the coverlay further covers a part of a lower side surface of the base film in the vertical direction, except for a region exposed to the outside in the first opening,
the metal plate is provided on a lower side surface of the coverlay in the vertical direction, and surrounds the electronic component,
in the first opening, the electrode is joined to the first joint region using a joint material,
in the second opening, one end of the metal plate is joined to the second joint region,
another end of the metal plate is joined to the bus bar, and
the electronic component is electrically connected to the bus bar via the conductor circuit and the metal plate.
